(19) United States
(12) Patent Application Publication
(10) Pub. No.: US 2025/0233572 A1
(43) Pub. Date: Jul. 17, 2025

(54) MULTILAYER ELECTRONIC COMPONENT

(71) Applicant: TDK Corporation, Tokyo (JP)

(72) Inventor: Kazuhiro TSUKAMOTO, Tokyo (JP)

(73) Assignee: TDK Corporation, Tokyo (JP)

(21) Appl. No.: 19/017,850

(22) Filed: Jan. 13, 2025

(30) Foreign Application Priority Data
Jan. 15, 2024 (JP) 2024-003786

(51) Int. Cl. H03H 7/01; H01F 17/00; H03H 1/00

(52) U.S. Cl. CPC H03H 7/0115; H01F 17/0013; H01F 2017/0026; H03H 2001/0085

(57) ABSTRACT

A multilayer electronic component includes a first inductor, a second inductor, a capacitor, and a multilayer stack. The first inductor and the second inductor are arranged so that a first opening of the first inductor and a second opening of the second inductor do not face each other. The capacitor includes a capacitor conductor layer. The capacitor conductor layer includes a first overlapping portion overlapping with at least one first inductor conductor layer forming the first inductor when seen in a stacking direction.

### CROSS-REFERENCE TO RELATED APPLICATION

This application claims the benefit of Japanese Priority Patent Application No. 2024-003786 filed on Jan. 15, 2024, the entire contents of which are incorporated herein by reference.

### BACKGROUND

The present disclosure relates to an electronic component including an inductor and a capacitor.

Various filters such as a low-pass filter, a high-pass filter, and a band-pass filter are configured by using a plurality of resonators. For example, an LC resonator configured by using an inductor and a capacitor is known as a resonator used in such a filter. An inductor configured by using a line is known. In general, a filter is provided with a plurality of inductors and a plurality of capacitors.

JP 2010-178380 A discloses a high-frequency switch module in which a low-pass filter and a high-pass filter are formed in a multilayer stack and a band-pass filter is mounted on the multilayer stack. The multilayer stack is provided with a plurality of transmission lines and a plurality of capacitors.

In recent years, the market has demanded a smaller, more space-efficient mobile communication apparatus, and there has also been a demand for a smaller filter to be used in the communication apparatus For a filter configured by using a multilayer stack, there is a demand to reduce the size of the multilayer stack while satisfying desired characteristics. In order to further reduce the size of the filter, it is needed to efficiently arrange a plurality of inductors and a plurality of capacitors within a multilayer stack. However, there is a limit in reducing the size of the multilayer stack by optimization of the arrangement of the plurality of inductors and the plurality of capacitors without losing a function of each of the plurality of inductors and the plurality of capacitors.

The problem described above applies not only to a filter but also to electronic components in general including inductors and capacitors.

### SUMMARY

A multilayer electronic component according to a first aspect of one embodiment of the present disclosure includes a first inductor, a second inductor, a capacitor, and a multilayer stack configured to integrate the first inductor, the second inductor, and the capacitor with each other and including a plurality of dielectric layers stacked together. The first inductor includes at least one first inductor conductor layer wound about a first axis extending in a direction parallel to a stacking direction of the plurality of dielectric layers. The second inductor includes at least one second inductor conductor layer wound about a second axis extending in a direction parallel to the stacking direction. The first inductor and the second inductor are arranged so that a first opening surrounded by the at least one first inductor conductor layer and a second opening surrounded by the at least one second inductor conductor layer do not overlap with each other when seen in the stacking direction. The capacitor includes a capacitor conductor layer. The capacitor conductor layer includes a first overlapping portion extending from the at least one second inductor conductor layer toward the at least one first inductor conductor layer when seen in the stacking direction and overlapping with the at least one first inductor conductor layer when seen in the stacking direction.

A multilayer electronic component according to a second aspect of one embodiment of the present disclosure includes an inductor, a capacitor, and a multilayer stack configured to integrate the inductor and the capacitor with each other and including a plurality of dielectric layers stacked together. The inductor includes at least one inductor conductor layer wound about an axis extending in a direction parallel to a stacking direction of the plurality of dielectric layers. The at least one inductor conductor layer includes an extending portion having a predetermined length and a smooth outer edge. The capacitor includes a capacitor conductor layer. The capacitor conductor layer includes a first overlapping portion extending from an outer side of the at least one inductor conductor layer toward an opening surrounded by the at least one inductor conductor layer when seen in the stacking direction and overlapping with the extending portion when seen in the stacking direction.

Other and further objects, features and advantages of the present disclosure appear more fully from the following description.

### BRIEF DESCRIPTION OF THE DRAWINGS

The attached drawings are included to facilitate understanding of the present disclosure, and are incorporated herein and form a part thereof. The drawings illustrate an example embodiment and, together with the description herein, serve to illustrate the principles of the present technique.

FIG. 1 is a circuit diagram illustrating a circuit configuration of an electronic component according to an example embodiment of the present disclosure.

FIG. 2 is a perspective view illustrating an electronic component according to the example embodiment of the present disclosure.

FIG. 3 is a perspective view illustrating a multilayer electronic component according to the example embodiment of the present disclosure.

FIG. 4 is a perspective view illustrating the multilayer electronic component according to the example embodiment of the present disclosure.

FIG. 5A to FIG. 5C are explanatory diagrams illustrating respective patterned surfaces of first to third dielectric layers in a multilayer stack of the multilayer electronic component according to the example embodiment of the present disclosure.

FIG. 6A is an explanatory diagram illustrating a pattered surface of a fourth dielectric layer in the multilayer stack of the multilayer electronic component according to the example embodiment of the present disclosure.

FIG. 6B is an explanatory diagram illustrating patterned surfaces of fifth and sixth dielectric layers in the multilayer stack of the multilayer electronic component according to the example embodiment of the present disclosure.

FIG. 6C is an explanatory diagram illustrating a pattered surface of a seventh dielectric layer in the multilayer stack of the multilayer electronic component according to the example embodiment of the present disclosure.

FIG. 7A is an explanatory diagram illustrating patterned surfaces of eighth and ninth dielectric layers in the multilayer stack of the multilayer electronic component according to the example embodiment of the present disclosure.

FIG. 7B and FIG. 7C are explanatory diagrams illustrating respective patterned surfaces of tenth and eleventh dielectric layers in the multilayer stack of the multilayer electronic component according to the example embodiment of the present disclosure.

FIG. 8A to FIG. 8C are explanatory diagrams illustrating respective patterned surfaces of twelfth to fourteenth dielectric layers in the multilayer stack of the multilayer electronic component according to the example embodiment of the present disclosure.

FIG. 9A to FIG. 9C are explanatory diagrams illustrating respective patterned surfaces of fifteenth to seventeenth dielectric layers in the multilayer stack of the multilayer electronic component according to the example embodiment of the present disclosure.

FIG. 10A and FIG. 10B are explanatory diagrams illustrating respective patterned surfaces of eighteenth to nineteenth dielectric layers in the multilayer stack of the multilayer electronic component according to the example embodiment of the present disclosure.

FIG. 10C is an explanatory diagram illustrating an electrode formation surface of the nineteenth dielectric layer.

FIG. 11 is a perspective view illustrating an inside of the multilayer stack of the multilayer electronic component according to the example embodiment of the present disclosure.

FIG. 12 is a plan view illustrating an inside of the multilayer electronic component according to the example embodiment of the present disclosure.

FIG. 13 is a circuit diagram illustrating a configuration of an inductor in the example embodiment of the present disclosure.

FIG. 14 is a plan view illustrating two inductors and a capacitor in the example embodiment of the present disclosure.

FIG. 15 is a plan view illustrating the two inductors and the capacitor in the example embodiment of the present disclosure.

FIG. 16 is an explanatory diagram illustrating arrangement of the two inductors and the capacitor in the multilayer stack in the example embodiment of the present disclosure.

FIG. 17 is a characteristic chart illustrating an example of pass attenuation characteristics of the electronic component according to the example embodiment of the present disclosure.

### DETAILED DESCRIPTION

An object of the present disclosure is to provide a multilayer electronic component that can be reduced in size without impairing a function of each of an inductor and a capacitor.

An example embodiment and a modification example of the present disclosure are described below in detail with reference to the attached drawings. Note that the following description is intended to illustrate the example embodiment of the present disclosure, and should not be construed as limiting the present technique. Elements including, but not limited to, numerical values, shapes, materials, constituent elements, positions of the constituent elements, and connection modes of the constituent elements are merely illustrative, and should not be construed as limiting the present technique. Furthermore, the elements in the following example embodiment that are not described in the broadest independent claims of the present disclosure are optional, and may be provided as required. The drawings are schematic, and are not intended to be illustrated to scale. To avoid redundant description, the same reference numerals are used for similar elements.

First, an overall configuration of an electronic component 1 including a multilayer electronic component according to the example embodiment of the present disclosure is described. The electronic component 1 according to the example embodiment is a band-pass filter that selectively allows a signal of a frequency in a predetermined passband to pass.

The electronic component 1 according to the example embodiment is a so-called hybrid-type filter that includes at least one LC resonator configured by using at least one inductor and at least one capacitor and an elastic wave resonator configured by using at least one elastic wave element. For example, the at least one elastic wave element may be a bulk elastic wave element or a surface acoustic wave element.

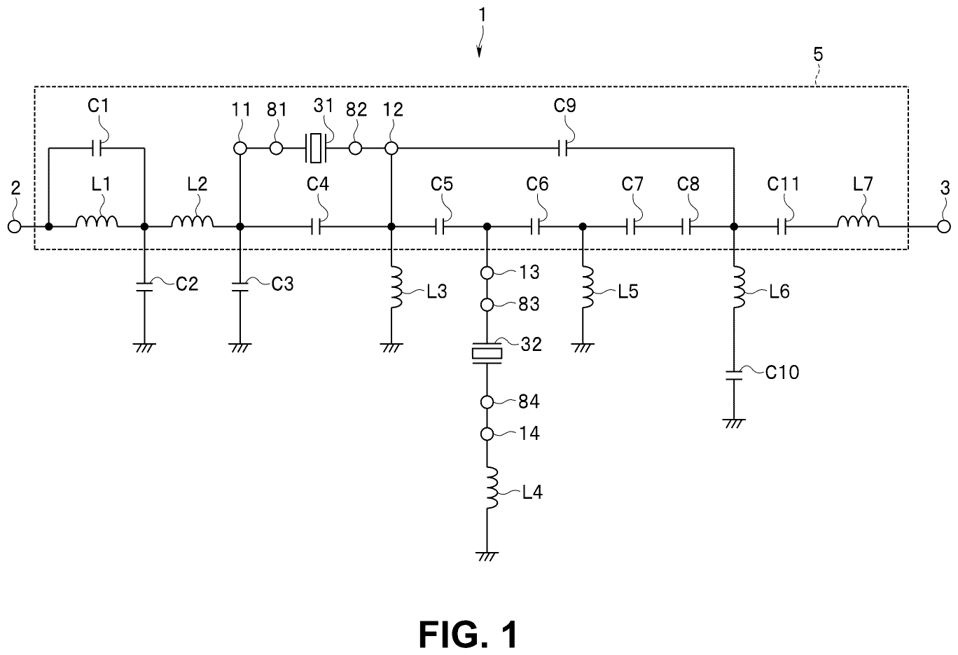

Next, with reference to FIG. 1, an example of a circuit configuration of the electronic component 1 is described. FIG. 1 is a circuit diagram illustrating the circuit configuration of the electronic component 1. The electronic component 1 includes a first input/output terminal 2, a second input/output terminal 3, and a filter circuit that is provided between the first input/output terminal 2 and the second input/output terminal 3 in circuit configuration. Note that, in the present application, the expression “in circuit configuration” is used to indicate layout in a circuit diagram instead of layout in a physical configuration.

Each of the first and second input/output terminals 2 and 3 is a terminal for inputting or outputting a signal. In other words, when a signal is input to the first input/output terminal 2, a signal is output from the second input/output terminal 3. When a signal is input to the second input/output terminal 3, a signal is output from the first input/output terminal 2.

The filter circuit includes inductors L1, L2, L3, L5, L6, and L7 and capacitors C1, C2, C3, C4, C5, C6, C7, C8, C9, C10, and C11. One end of the inductor L1 is connected to the first input/output terminal 2. One end of the inductor L2 is connected to the other end of the inductor L1.

One end of the capacitor C4 is connected to the other end of the inductor L2. One end of the capacitor C5 is connected to the other end of the capacitor C4. One end of the capacitor C6 is connected to the other end of the capacitor C5. One end of the capacitor C7 is connected to the other end of the capacitor C6. One end of the capacitor C8 is connected to the other end of the capacitor C7.

One end of the capacitor C11 is connected to the other end of the capacitor C8. One end of the inductor L7 is connected to the other end of the capacitor C11. The other end of the inductor L7 is connected to the second input/output terminal 3.

The capacitor C1 is connected in parallel to the inductor L1. One end of the capacitor C2 is connected to a connection point between the inductor L1 and the inductor L2. One end of the capacitor C3 is connected to a connection point between the inductor L2 and the capacitor C4. The other end of each of the capacitors C2 and C3 is connected to the ground.

One end of the inductor L3 is connected to a connection point between the capacitor C4 and the capacitor C5. One end of the inductor L5 is connected to a connection point between the capacitor C6 and the capacitor C7. The other end of each of the inductors L3 and L5 is connected to the ground.

One end of the inductor L6 is connected to a connection point between the capacitor C8 and the capacitor C11. One end of the capacitor C10 is connected to the other end of the inductor L6. The other end of the capacitor C10 is connected to the ground.

One end of the capacitor C9 is connected to the one end of each of the inductor L3 and the capacitor C5. The other end of the capacitor C9 is connected to the one end of the inductor L6 and the other end of the capacitor C8.

The filter circuit further includes signal terminals 81, 82, 83, and 84, an elastic wave element 31 that is arranged between the signal terminal 81 and the signal terminal 82 in circuit configuration, and an elastic wave element 32 that is arranged between the signal terminal 83 and the signal terminal 84 in circuit configuration.

The filter circuit further includes signal terminals 11, 12, 13, and 14 that are connected to the signal terminals 81, 82, 83, and 84, respectively. Note that, in FIG. 1, for the sake of convenience, the signal terminal 12 is illustrated as being interposed between the one end of the capacitor C9 and the one end of the capacitor C5. However, the signal terminal 12 may not be interposed between the one end of the capacitor C9 and the one end of the capacitor C5.

The capacitor C4 is connected in parallel to the elastic wave element 31. The other end of the inductor L2 and the one end of each of the capacitors C3 and C4 are connected to one end of the elastic wave element 31 via the signal terminals 11 and 81 in sequence. The one end of the inductor L3, the other end of the capacitor C4, and the one end of the capacitor C5 are connected to the other end of the elastic wave element 31 via the signal terminals 12 and 82 in sequence.

The other end of the capacitor C5 and the one end of the capacitor C6 are connected to one end of the elastic wave element 32 via the signal terminals 13 and 83 in sequence. The filter circuit further includes an inductor L4. One end of the inductor L4 is connected to the other end of the elastic wave element 32 via the signal terminals 14 and 84 in sequence. The other end of the inductor L4 is connected to the ground.

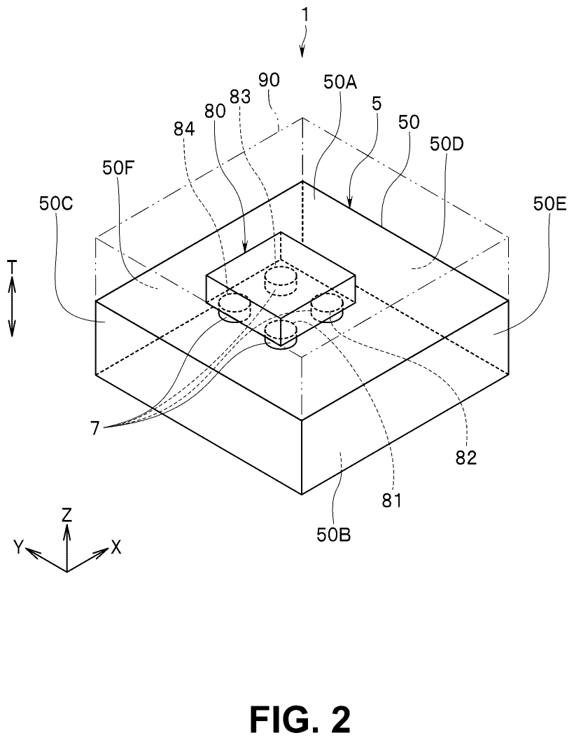

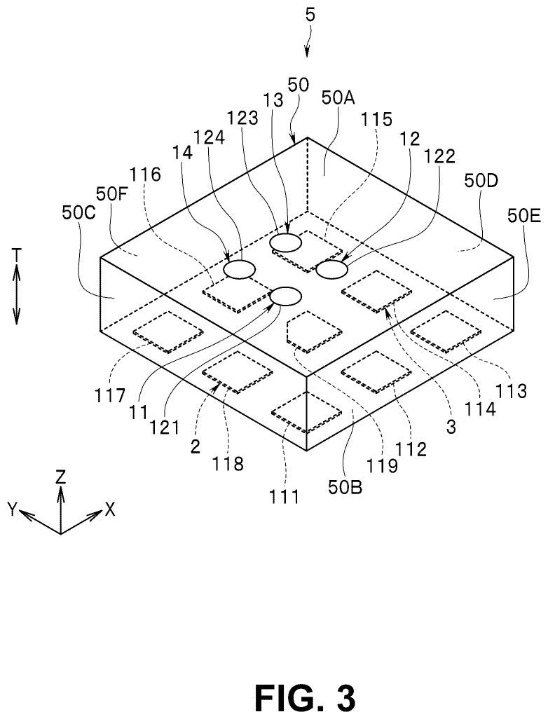

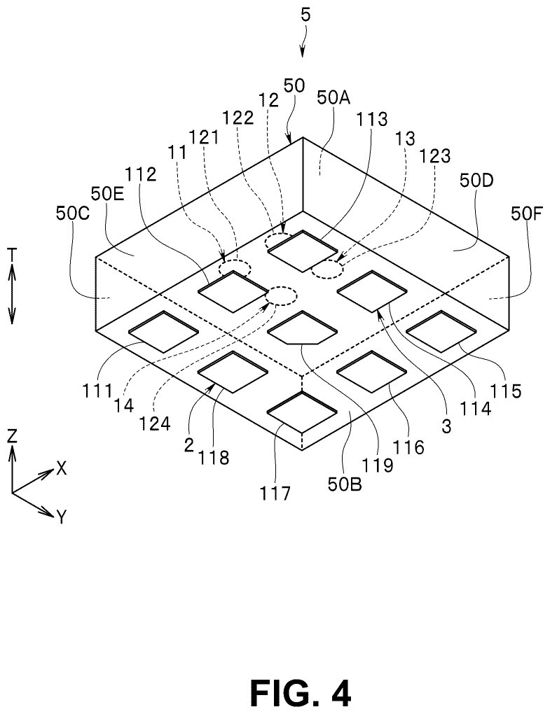

Next, with reference to FIG. 2 to FIG. 4, a configuration of a multilayer electronic component according to the example embodiment is described. FIG. 2 is a perspective view illustrating the electronic component 1. FIG. 3 and FIG. 4 are perspective views illustrating the multilayer electronic component according to the example embodiment.

The electronic component 1 includes a multilayer electronic component 5 according to the example embodiment. The multilayer electronic component 5 includes a multilayer stack 50 including a plurality of dielectric layers stacked together and a plurality of conductors (a plurality of conductor layers and a plurality of through holes). The multilayer stack 50 integrates the inductors L1 to L7 and the capacitors C1 to C11 with each other in the filter circuit illustrated in FIG. 1. The inductors L1 to L7 and the capacitors C1 to C11 are configured by using a plurality of conductors. Each of the plurality of dielectric layers is configured by a dielectric material. For example, low-temperature co-fired ceramics (LTCC) are used as the dielectric material.

The multilayer stack 50 includes a first surface 50A and a second surface 50B that are located at both the ends thereof in a stacking direction T of the plurality of dielectric layers and four side surfaces 50C to 50F that connect the first surface 50A and the second surface 50B. The side surfaces 50C and 50D are opposite to each other, and the side surfaces 50E and 50F are opposite to each other. The side surfaces 50C to 50F are perpendicular to the first surface 50A and the second surface 50B.

Here, X, Y, and Z directions are defined as shown in FIGS. 2 to 4. The X direction, the Y direction, and the Z direction are orthogonal to one another. In the example embodiment, it is assumed that one direction parallel to the stacking direction T is the Z direction. It is assumed that a direction opposite to the X direction is a −X direction, a direction opposite to the Y direction is a −Y direction, and a direction opposite to the Z direction is a −Z direction. The expression “when seen in a predetermined direction (for example, the Z direction)” indicates that a target object is viewed from a position away from the target object in the predetermined direction or one direction parallel to the predetermined direction.

As illustrated in FIG. 3 and FIG. 4, the first surface 50A is located at the end of the multilayer stack 50 in the Z direction. The first surface 50A is an upper surface of the multilayer stack 50, and is also a mounting surface on which a mounting member described below is mounted. The second surface 50B is located at the end of the multilayer stack 50 in the −Z direction. The second surface 50B is also a bottom surface of the multilayer stack 50. FIG. 3 illustrates the multilayer stack 50 as viewed from the first surface 50A side. FIG. 4 illustrates the multilayer stack 50 as viewed from the second surface 50B side.

The side surface 50C is located at the end of the multilayer stack 50 in the −X direction. The side surface 50D is located at the end of the multilayer stack 50 in the X direction. The side surface 50E is located at the end of the multilayer stack 50 in the −Y direction. The side surface 50F is located at the end of the multilayer stack 50 in the Y direction.

The multilayer stack 50 further includes a plurality of electrodes 111, 112, 113, 114, 115, 116, 117, 118, and 119 that are provided to the second surface 50B of the multilayer stack 50. The electrodes 111, 112, and 113 are arrayed in the X direction in the stated order at positions closer to the side surface 50E with respect to the side surface 50F. The electrodes 115, 116, and 117 are arrayed in the −X direction in the stated order at positions closer to the side surface 50F with respect to the side surface 50E.

The electrode 114 is arranged between the electrode 113 and the electrode 115. The electrode 118 is arranged between the electrode 111 and the electrode 117. The electrode 119 is arranged between the electrode 112 and the electrode 116. The electrode 119 is arranged substantially at the center of the second surface 50B.

The electrode 118 corresponds to the first input/output terminal 2. The electrode 114 corresponds to the second input/output terminal 3. Thus, the first and second input/output terminals 2 and 3 are provided to the second surface 50B of the multilayer stack 50. Each of the electrodes 111 to 113, 115 to 117, and 119 is connected to the ground.

The multilayer stack 50 further includes a plurality of electrodes 121, 122, 123, and 124 that are provided to the first surface 50A of the multilayer stack 50. The electrodes 121 and 122 are arrayed in the X direction in the stated order at positions closer to the side surface 50E with respect to the side surface 50F. The electrodes 123 and 124 are arrayed in the −X direction in the stated order at positions closer to the side surface 50F with respect to the side surface 50E.

The electrode 121 corresponds to the signal terminal 11. The electrode 122 corresponds to the signal terminal 12. The electrode 123 corresponds to the signal terminal 13. The electrode 124 corresponds to the signal terminal 14. Thus, the signal terminals 11 to 14 are provided to the first surface 50A of the multilayer stack 50.

The electronic component 1 further includes a mounting member 80 mounted on the first surface 50A of the multilayer stack 50. The mounting member 80 includes the elastic wave elements 31 and 32 in the filter circuit illustrated in FIG. 1.

The mounting member 80 further includes four electrodes forming the signal terminals 81, 82, 83, and 84, respectively. Note that, in FIG. 2, for the sake of convenience, the four electrodes are denoted with the reference numerals 81 to 84. While the mounting member 80 is mounted on the multilayer stack 50, the four electrodes denoted with the reference numerals 81 to 84 face the electrodes 121 to 124 of the multilayer stack 50, respectively. For example, the four electrodes denoted with the reference numerals 81 to 84 are physically connected to the electrodes 121 to 124 by solder bumps 7.

In the example illustrated in FIG. 2, the mounting member 80 is arranged so as to overlap with the center of gravity of the first surface 50A when seen in the stacking direction T. The center of gravity of the mounting member 80 when seen in the stacking direction T may or may not match with the center of gravity of the first surface 50A.

The electronic component 1 further includes a sealing portion 90 that seals the mounting member 80. The sealing portion 90 covers the periphery of the mounting member 80 and at least a part of the first surface 50A of the multilayer stack 50. The sealing portion 90 may further cover the side surfaces 50C to 50F of the multilayer stack 50. For example, the sealing portion 90 is configured by a resin.

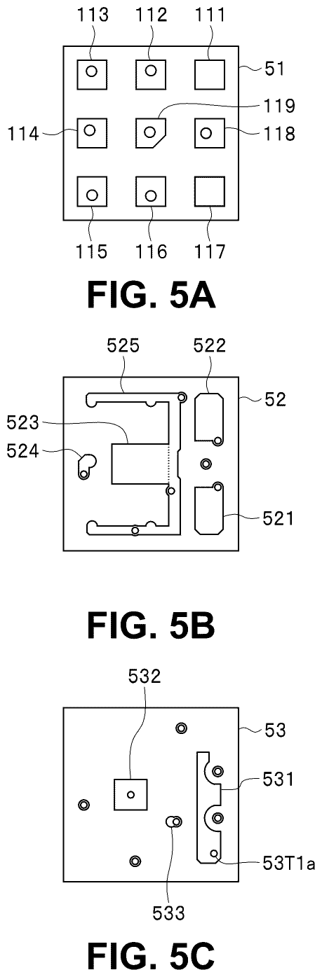

Next, with reference to FIG. 5A to FIG. 10C, an example of the plurality of dielectric layers, the plurality of conductor layers, and the plurality of through holes that form the multilayer stack 50 is described. In this example, the multilayer stack 50 includes nineteen dielectric layers stacked together. Hereinafter, the nineteen dielectric layers are referred to as first to nineteenth dielectric layers in the order form bottom to top. The first to nineteenth dielectric layers are denoted with the reference numerals 51 to 69, respectively.

In FIG. 5A to FIG. 10B, a plurality of circles indicate the plurality of through holes. The plurality of through holes are formed in each of the dielectric layers 51 to 69. Each of the plurality of through holes is formed by filling a hole for a through hole with a conductor paste. Each of the plurality of through holes is connected to an electrode, a conductor layer, or another through hole.

In FIG. 5A to FIG. 10B, a plurality of specific through holes of the plurality of through holes are denoted with reference numeral. A connection relationship between each of the plurality of specific through holes, and an electrode, a conductor layer, or another through hole is described as a connection relationship in a state in which the first to nineteenth dielectric layers 51 to 69 are stacked.

FIG. 5A illustrates a patterned surface of the first dielectric layer 51. The electrodes 111 to 119 are formed on the patterned surface of the dielectric layer 51.

FIG. 5B illustrates a patterned surface of the second dielectric layer 52. Conductor layers 521, 522, 523, 524, and 525 are formed on the patterned surface of the dielectric layer 52. The conductor layer 525 is connected to the conductor layer 523. In FIG. 5B, the boundary between the conductor layer 523 and the conductor layer 525 is indicated by a dotted line.

FIG. 5C illustrates a patterned surface of the third dielectric layer 53. Conductor layers 531, 532, and 533 are formed on the patterned surface of the dielectric layer 53. The through hole denoted with the reference numeral 53T1a in FIG. 5C is connected to the conductor layer 531. Note that, in the following description, a through hole denoted with the reference numeral 53T1a is simply described as a through hole 53T1a. Through holes denoted with reference numerals other than the through hole 53T1a are described similarly to the through hole 53T1a.

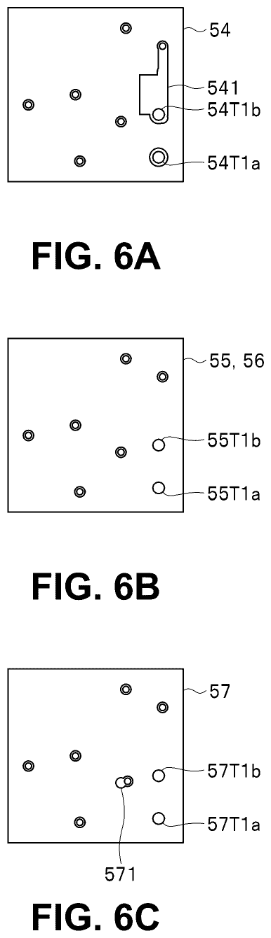

FIG. 6A illustrates a patterned surface of the fourth dielectric layer 54. A conductor layer 541 is formed on the patterned surface of the dielectric layer 54. The through hole 54T1b illustrated in FIG. 6A is connected to the conductor layer 541. The through hole 53T1a is connected to the through hole 54T1a illustrated in FIG. 6A.

FIG. 6B illustrates respective patterned surfaces of the fifth and sixth dielectric layers 55 and 56. The through holes 54T1a and 54T1b are connected to the through holes 55T1a and 55T1b formed in the dielectric layer 55, respectively. In the dielectric layers 55 and 56, vertically adjacent through holes denoted by the same reference numerals are connected to each other.

FIG. 6C illustrates a patterned surface of the seventh dielectric layer 57. A conductor layer 571 is formed on the patterned surface of the dielectric layer 57. The through holes 55T1a and 55T1b formed in the dielectric layer 56 are connected to the through holes 57T1a and 57T1b illustrated in FIG. 6C, respectively.

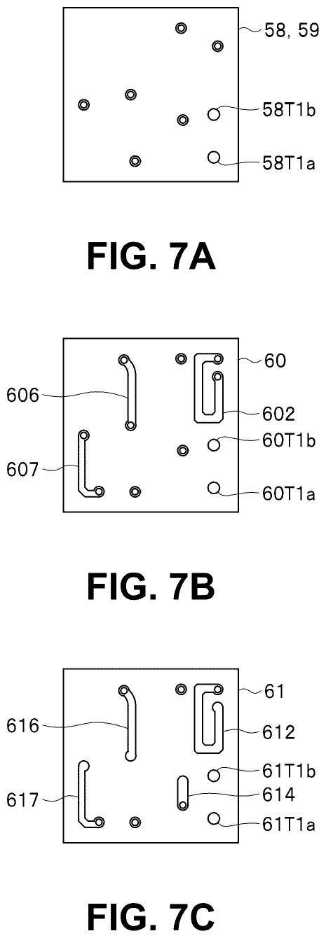

FIG. 7A illustrates respective patterned surfaces of the eighth and ninth dielectric layers 58 and 59. The through holes 57T1a and 57T1b are connected to the through holes 58T1a and 58T1b formed in the dielectric layer 58, respectively. In the dielectric layers 58 and 59, vertically adjacent through holes denoted by the same reference numerals are connected to each other.

FIG. 7B illustrates a patterned surface of the tenth dielectric layer 60. Inductor conductor layers 602, 606, and 607 are formed on the patterned surface of the dielectric layer 60. The through holes 58T1a and 58T1b formed in the dielectric layer 59 are connected to the through holes 60T1a and 60T1b illustrated in FIG. 7B, respectively.

FIG. 7C illustrates a patterned surface of the eleventh dielectric layer 61. Inductor conductor layers 612, 614, 616, and 617 are formed on the patterned surface of the dielectric layer 61. The through holes 60T1a and 60T1b are connected to the through holes 61T1a and 61T1b illustrated in FIG. 7C, respectively.

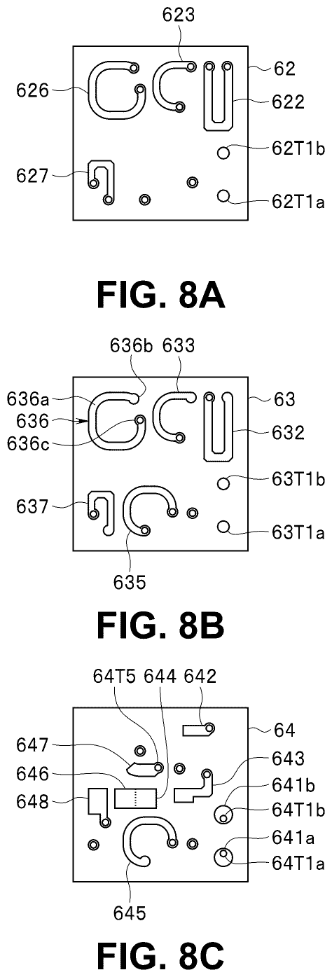

FIG. 8A illustrates a patterned surface of the twelfth dielectric layer 62. Inductor conductor layers 622, 623, 626, and 627 are formed on the patterned surface of the dielectric layer 62. The through holes 61T1a and 61T1b are connected to the through holes 62T1a and 62T1b illustrated in FIG. 8A, respectively.

FIG. 8B illustrates a patterned surface of the thirteenth dielectric layer 63. Inductor conductor layers 632, 633, 635, 636, and 637 are formed on the patterned surface of the dielectric layer 63. The through holes 62T1a and 62T1b are connected to the through holes 63T1a and 63T1b illustrated in FIG. 8B, respectively.

FIG. 8C illustrates a patterned surface of the fourteenth dielectric layer 64. Conductor layers 641a, 641b, 642, 643, 644, 646, 647, and 648, and an inductor conductor layer 645 are formed on the patterned surface of the dielectric layer 64. The conductor layer 646 is connected to the conductor layer 644. In FIG. 8C, the boundary between the conductor layer 644 and the conductor layer 646 is indicated by a dotted line. The through hole 63T1a and the through hole 64T1a illustrated in FIG. 8C are connected to the conductor layer 641a. The through hole 63T1b and the through hole 64T1b illustrated in FIG. 8C are connected to the conductor layer 641b. The through hole 64T5 illustrated in FIG. 8C is connected to the conductor layer 647.

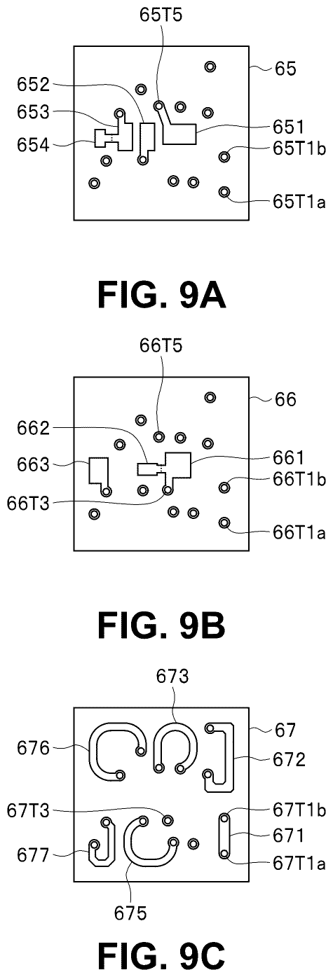

FIG. 9A illustrates a patterned surface of the fifteenth dielectric layer 65. Conductor layers 651, 652, 653, and 654 are formed on the patterned surface of the dielectric layer 65. The conductor layer 654 is connected to the conductor layer 653. In FIG. 9A, the boundary between the conductor layer 653 and the conductor layer 654 is indicated by a dotted line. The through holes 64T1a and 64T1b are connected to the through holes 65T1a and 65T1b illustrated in FIG. 9A, respectively. The through hole 64T5 and the through hole 65T5 illustrated in FIG. 9A are connected to the conductor layer 651.

FIG. 9B illustrates a patterned surface of the sixteenth dielectric layer 66. Conductor layers 661, 662, and 663 are formed on the patterned surface of the dielectric layer 66. The conductor layer 662 is connected to the conductor layer 661. In FIG. 9B, the boundary between the conductor layer 661 and the conductor layer 662 is indicated by a dotted line. The through holes 65T1a and 65T1b are connected to the through holes 66T1a and 66T1b illustrated in FIG. 9B, respectively. The through hole 66T3 illustrated in FIG. 9B is connected to the conductor layer 661. The through hole 65T5 is connected to the through hole 66T5 illustrated in FIG. 9B.

FIG. 9C illustrates a patterned surface of the seventeenth dielectric layer 67. Inductor conductor layers 671, 672, 673, 675, 676, and 677 are formed on the patterned surface of the dielectric layer 67. The conductor layer 671 includes a first end and a second end that are located on opposite sides in the longitudinal direction of the conductor layer 671. The through hole 66T1a and the through hole 67T1a illustrated FIG. 9C are connected to the vicinity of the first end of the conductor layer 671. The through hole 66T1b and the through hole 67T1b illustrated in FIG. 9C are connected to the vicinity of the second end of the conductor layer 671. The through hole 66T3 is connected to the through hole 67T3 illustrated in FIG. 9C. The through hole 66T5 is connected to the conductor layer 673.

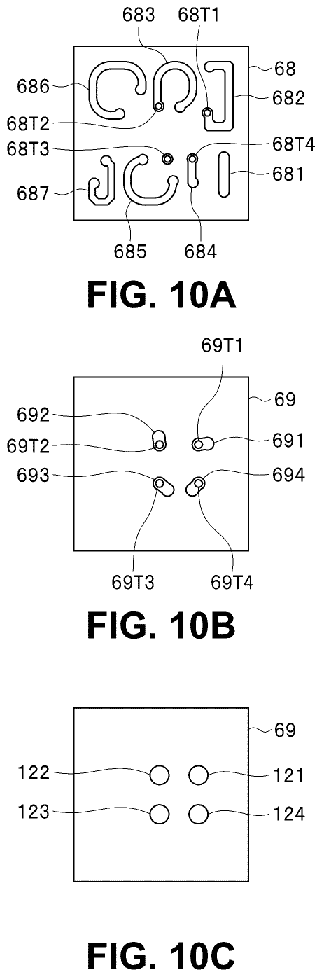

FIG. 10A illustrates a patterned surface of the eighteenth dielectric layer 68. Inductor conductor layer 681, 682, 683, 684, 685, 686, and 687 are formed on the patterned surface of the dielectric layer 68. The conductor layer 681 includes a first end and a second end that are located on opposite sides in the longitudinal direction of the conductor layer 681. The through hole 67T1a is connected to the vicinity of the first end of the conductor layer 681. The through hole 67T1b is connected to the vicinity of the second end of the conductor layer 681. The through holes 68T1, 68T2, and 68T4 illustrated in FIG. 10A are connected to the conductor layer 682, 683, and 684, respectively. The through hole 67T3 is connected to the through hole 68T3 illustrated in FIG. 10A.

FIG. 10B illustrates a patterned surface of the nineteenth dielectric layer 69. Conductor layers 691, 692, 693, and 694 are formed on the patterned surface of the dielectric layer 69. The through hole 68T1 and the through hole 69T1 illustrated in FIG. 10B are connected to the conductor layer 691. The through hole 68T2 and the through hole 69T2 illustrated in FIG. 10B are connected to the conductor layer 692. The through hole 68T3 and the through hole 69T3 illustrated in FIG. 10B are connected to the conductor layer 693. The through hole 68T4 and the through hole 69T4 illustrated in FIG. 10B are connected to the conductor layer 694.

FIG. 10C illustrates a surface opposite to the patterned surface of the nineteenth dielectric layer 69. Hereinafter, the surface opposite to the patterned surface of the dielectric layer 69 refers to an electrode formation surface of the dielectric layer 69. The electrodes 121, 122, 123, and 124 are formed on the electrode formation surface of the dielectric layer 69. The through holes 69T1, 69T2, 69T3, and 69T4 are connected to the electrode 121, 122, 123, and 124, respectively.

The multilayer stack 50 is formed by stacking the first to nineteenth dielectric layers 51 to 69 so that the patterned surface of the first dielectric layer 51 serves as the second surface 50B of the multilayer stack 50, and the electrode formation surface of the nineteenth dielectric layer 69 serves as the first surface 50A of the multilayer stack 50.

Each of the plurality of through holes illustrated in FIG. 5A to FIG. 10B is connected to a conductor layer overlapping in the stacking direction T or another through hole overlapping in the stacking direction T when the first to nineteenth dielectric layers 51 to 69 are stacked. Among the plurality of through holes illustrated in FIG. 5A to FIG. 10B, a through hole located within an electrode or a conductor layer is connected to the electrode or the conductor layer.

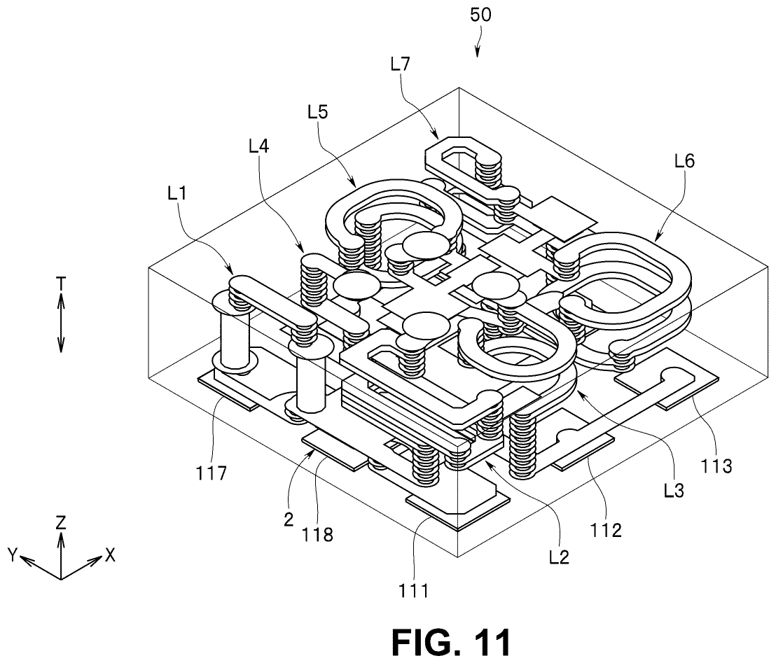

FIG. 11 illustrates an inside of the multilayer stack 50 formed by stacking the first to nineteenth dielectric layers 51 to 69 together. As illustrated in FIG. 11, inside the multilayer stack 50, the plurality of conductor layers and the plurality of through holes illustrated in FIG. 5A to FIG. 10C are stacked together.

The correspondence between the constituent elements of the circuit of the electronic component 1 illustrated in FIG. 1 and the constituent elements inside the multilayer stack 50 illustrated in FIG. 5A to FIG. 10C is described below. The inductor L1 is formed by the inductor conductor layers 671 and 681, the conductor layers 641a and 641b, and the through holes 53T1a, 54T1a, 54T1b, 55T1a, 55T1b, 57T1a, 57T1b, 58T1a, 58T1b, 60T1a, 60T1b, 61T1a, 61T1b, 62T1a, 62T1b, 63T1a, 63T1b, 64T1a, 64T1b, 65T1a, 65T1b, 66T1a, 66T1b, 67T1a, and 67T1b.

The inductor L2 is formed by the inductor conductor layers 602, 612, 622, 632, and 672, 682 and the plurality of through holes that connect those conductor layers. The conductor layer 682 is connected to the electrode 121 via the through hole 68T1, the conductor layer 691, and the through hole 69T1.

The inductor L3 is formed by the inductor conductor layers 623, 633, 673, and 683 and the plurality of through holes that connect those conductor layers. The conductor layer 683 is connected to the electrode 122 via the through hole 68T2, the conductor layer 692, and the through hole 69T2.

The inductor L4 is formed by the inductor conductor layers 614 and 684, the conductor layers 533 and 571, the plurality of through holes that connect the conductor layers 614 and 684, the plurality of through holes that connect the conductor layers 571 and 614, the plurality of through holes that connect the conductor layers 533 and 571, and the through hole that connects the conductor layers 525 and 533. The conductor layer 684 is connected to the electrode 124 via the through hole 68T4, the conductor layer 694, and the through hole 69T4.

The inductor L5 is formed by the inductor conductor layers 635, 645, 675, and 685 and the plurality of through holes that connect those conductor layers. The inductor L6 is formed by the inductor conductor layers 606, 616, 626, 636, 676, and 686 and the plurality of through holes that connect those conductor layers. The inductor L7 is formed by the inductor conductor layers 607, 617, 627, 637, 677, and 687 and the plurality of through holes that connect those conductor layers.

The capacitor C1 is formed by the conductor layers 521, 522, 531, and 541 and the dielectric layers 52 and 53 between those conductor layers. The capacitor C2 is formed by the electrodes 111 and 117, the conductor layers 521 and 522, and the dielectric layer 51 between the electrodes 111 and 117 and the conductor layers 521 and 522.

The capacitor C3 is formed by the conductor layers 633 and 642 and the dielectric layer 63 between those conductor layers. The capacitor C4 is formed by the conductor layers 643 and 651 and the dielectric layer 64 between those conductor layers.

The capacitor C5 is formed by the conductor layers 651 and 661 and the dielectric layer 65 between those conductor layers. The conductor layer 661 is connected to the electrode 123 via the through holes 66T3, 67T3, and 68T3, the conductor layer 693, and the through hole 69T3.

The capacitor C6 is formed by the conductor layers 652 and 662 and the dielectric layer 65 between those conductor layers. The capacitor C7 is formed by the conductor layers 644 and 652 and the dielectric layer 64 between those conductor layers. The capacitor C8 is formed by the conductor layers 646 and 653 and the dielectric layer 64 between those conductor layers.

The capacitor C9 is formed by the conductor layers 636 and 647 and the dielectric layer 63 between those conductor layers. The conductor layer 647 is connected to the inductor conductor layer 673 forming the inductor L3 via the through holes 64T5, 65T5, and 66T5.

The capacitor C10 is formed by the conductor layers 523 and 532 and the dielectric layer 52 between those conductor layers. The capacitor C11 is formed by the conductor layers 648, 654, and 663 and the dielectric layers 64 and 65 between those conductor layers.

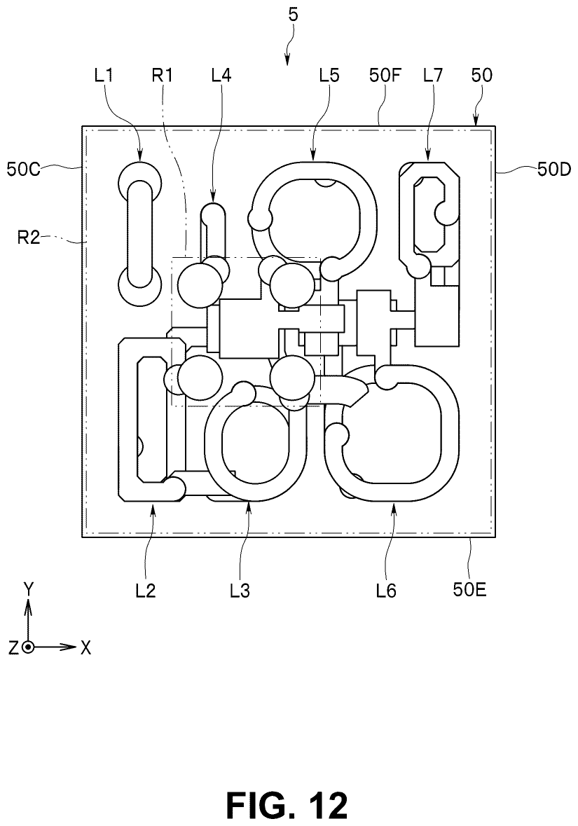

Next, with reference to FIG. 2 to FIG. 12, structural features of the multilayer electronic component 5 according to the example embodiment are described. FIG. 12 is a plan view illustrating an inside of the multilayer electronic component 5.

First, two regions of the multilayer electronic component 5 that are defined by the mounting member 80 are described. As described above, the mounting member 80 is mounted on the first surface 50A of the multilayer stack 50. The multilayer electronic component 5 includes a first region R1 that overlaps with the mounting member 80 when seen in the stacking direction T and a second region R2 that does not overlap with the mounting member 80 when seen in the stacking direction T. The first region R1 is defined as a three-dimensional region that includes an end in the Z direction on the first surface 50A and an end in the −Z direction on the second surface 50B. In FIG. 12, an outer edge of the first region R1 that includes ends of the first region R1 in the X direction, the −X direction, the Y direction, and the −Y direction is indicated with a rectangular two-dot chain line denoted with the reference numeral R1.

The second region R2 is substantially defined as a region obtained by excluding the first region R1 from a three-dimensional region surrounded by the outer surfaces of the multilayer stack 50. The second region R2 covers at least a part of the outer peripheral portion of the first region R1. Particularly in the example embodiment, the second region R2 covers a part of the outer peripheral portion of the first region R1, except for the end in the Z direction (the first surface 50A) and the end in the −Z direction (the second surface 50B). In FIG. 12, the outer edge of the second region R2 that includes the ends of the second region R2 in the X direction, the −X direction, the Y direction, and the −Y direction is indicated with a rectangular two-dot chain line denoted with the reference numeral R2. Note that, in FIG. 12, for the sake of convenience, the outer edge of the second region R2 is illustrated away from the side surfaces 50C to 50F of the multilayer stack 50.

The planar shape of the mounting member 80 (the shape thereof when seen in the stacking direction T) may be the same as the shape of the first region R1. Alternatively, the mounting member 80 may include a first portion having the same planar shape as the shape of the first region R1 and a second portion having a size of a planar shape that is different from the size of the planar shape of the first region R1. In this case, the mounting member 80 is mounted on the multilayer stack 50 in such a posture that the first portion is located between the multilayer stack 50 and the second portion.

Next, features of the inductors L2, L3, L5, L6, and L7 are described. The inductor L2 is wound about an axis extending in a direction parallel to the stacking direction T so as to form an opening surrounded by the inductor L2. Hereinafter, an opening surrounded by the inductor L2 is referred to as an opening of the inductor L2. The opening of the inductor L2 faces the first surface 50A of the multilayer stack 50. The opening of the inductor L2 is entirely present in the second region R2. Hereinafter, with regard to the inductors other than the inductor L2, openings surrounded by the inductors are also referred to as openings of the inductors.

Similarly, each of the inductors L3, L5, and L6, L7 is wound about an axis extending in a direction parallel to the stacking direction T so as to form an opening surrounded by each of the inductors L3, L5, L6, and L7. The opening of each of the inductors L3, L5, L6, and L7 faces the first surface 50A of the multilayer stack 50. The opening of each of the inductors L3 and L5 is mostly present in the second region R2. The opening of each of the inductors L6 and L7 is mostly present in the second region R2.

The inductor L2 includes the plurality of inductor conductor layers 602, 612, 622, 632, 672, and 682 that are arranged at a predetermined interval in the stacking direction T. Each of the conductor layers 602, 612, 622, 632, 672, and 682 is wound about an axis extending in a direction parallel to the stacking direction T so as to surround the opening of the inductor L2.

The inductor L3 includes the plurality of inductor conductor layers 623, 633, 673, and 683 that are arranged at a predetermined interval in the stacking direction T. Each of the conductor layers 623, 633, 673, and 683 is wound about an axis extending in a direction parallel to the stacking direction T so as to surround the opening of the inductor L3.

The inductor L5 includes the plurality of inductor conductor layers 635, 645, 675, and 685 that are arranged at a predetermined interval in the stacking direction T. Each of the conductor layers 635, 645, 675, and 685 is wound about an axis extending in a direction parallel to the stacking direction T so as to surround the opening of the inductor L5.

The inductor L6 includes the plurality of inductor conductor layers 606, 616, 626, 636, 676, and 686 that are arranged at a predetermined interval in the stacking direction T. Each of the conductor layers 626, 636, 676, and 686 is wound about an axis extending in a direction parallel to the stacking direction T so as to surround the opening of the inductor L6. Each of the conductor layers 606 and 616 extends along the opening of the inductor L6.

The inductor L7 includes the plurality of inductor conductor layers 607, 617, 627, 637, 677, and 687 that are arranged at a predetermined interval in the stacking direction T. Each of the conductor layers 627, 637, 677, and 687 is wound about an axis extending in a direction parallel to the stacking direction T so as to surround the opening of the inductor L7. Each of the conductor layers 607 and 617 extends along the opening of the inductor L7.

Next, features of the inductors L1 and L4 are described. The inductor L1 is wound about an axis extending in a direction orthogonal to the stacking direction T so as to form an opening surrounded by the inductor L1. The opening of the inductor L1 faces the side surface 50C of the multilayer stack 50.

The inductor L4 has such a shape that an opening surrounded by the inductor L4 is not formed.

Next, features of a relationship between the inductors L3 and L6 and the capacitor C9 are described. As illustrated in FIG. 1, in circuit configuration, the elastic wave element 32, the inductors L4 and L5, and the capacitors C5, C6, C7, and C8 are provided between the inductor L3 and the inductor L6. The inductor L3 and the inductor L6 are capacitively cross-coupled by the capacitor C9.

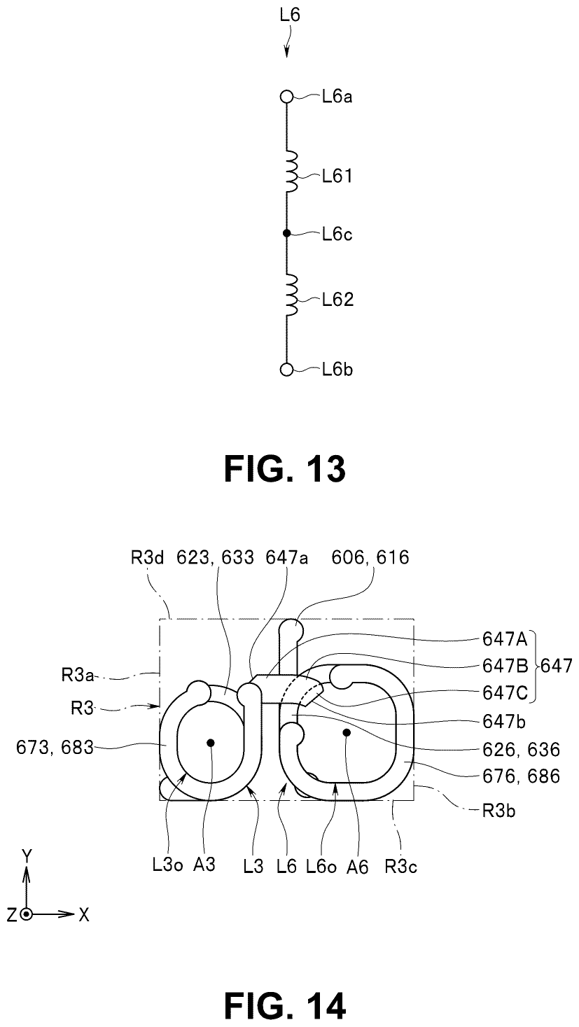

Here, with reference to FIG. 13, connection between the inductor L6 and the capacitor C9 is described. FIG. 13 is a circuit diagram illustrating a configuration of the inductor L6. The inductor L6 can be divided into two inductor portions L61 and L62. The two inductor portions L61 and L62 are connected in series. In FIG. 13, the reference numeral L6a denotes a first end of the inductor L6, the reference numeral L6b denotes a second end of the inductor L6, and the reference numeral L6c denotes a joint point located between the two inductor portions L61 and L62. The second end L6b of the inductor L6 is connected to the ground.

In FIG. 1, for the sake of convenience, the one end of the capacitor C9 is illustrated as being connected to the first end L6a of the inductor L6. However, the one end of the capacitor C9 may be connected to the first end L6a of the inductor L6 in circuit configuration, or may be connected between the first end L6a and the second end L6b of the inductor L6 in circuit configuration. In the examples of the plurality of conductor layers and the plurality of through holes illustrated in FIG. 5A to FIG. 12, the one end of the capacitor C9 is connected between the first end L6a and the second end L6b of the inductor L6 in circuit configuration.

When the one end of the capacitor C9 is connected to the joint point L6c of the inductor L6 that is located between the first end L6a and the second end L6b of the inductor L6, a physical connection position of the capacitor C9 at the inductor L6 is adjusted, and thus an inductance of each of the inductor portions L61 and L62 can be adjusted. In this case, a substantial impedance of the inductor L6 is determined by an inductance of the inductor portion L62. A substantial impedance of the inductor L6 can be adjusted by adjusting a physical connection position of the capacitor C9 at the inductor L6.

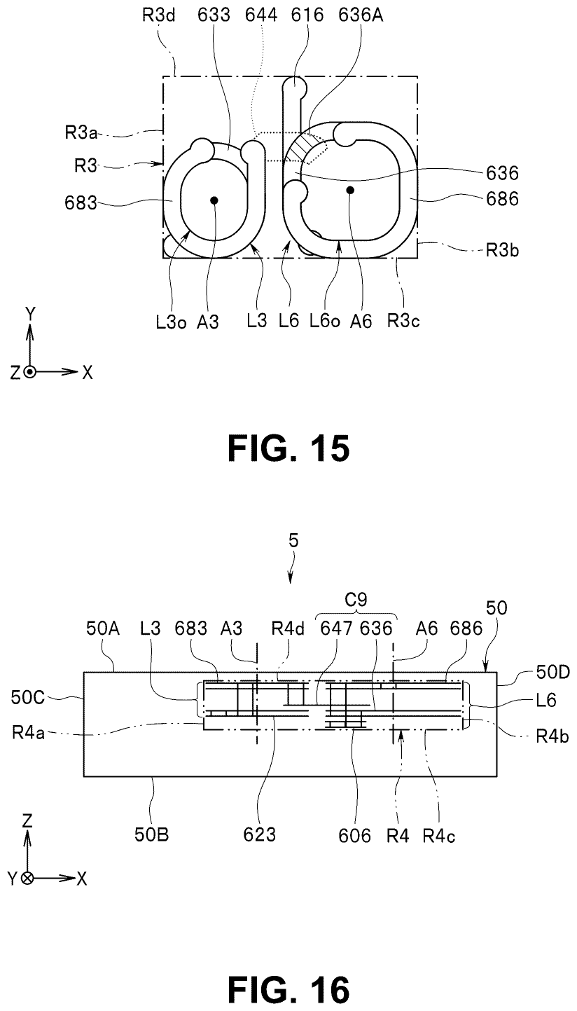

Next, with reference to FIG. 14 to FIG. 16, features of arrangement of the inductors L3 and L6 and the capacitor C9 are described. FIG. 14 and FIG. 15 are plane views illustrating the inductors L3 and L6 and the capacitor C9. FIG. 16 is an explanatory diagram illustrating arrangement of the inductors L3 and L6 and the capacitor C9 in the multilayer stack 50. In FIG. 14 and FIG. 15, the reference numeral L30 denotes an opening of the inductor L3, and the reference numeral L60 denotes an opening of the inductor L6.

As described above, the inductor L3 is formed by the inductor conductor layers 623, 633, 673, and 683 and the plurality of through holes connected to those conductor layers. In FIG. 14 to FIG. 16, the reference numeral A3 denotes an axis that passes through the opening L30 of the inductor L3 and extends in a direction parallel to the stacking direction T. The conductor layers 623, 633, 673, and 683 as a whole are wound about the axis A3. Particularly in the example embodiment, each of the conductor layers 623, 633, 673, and 683 is wound about the axis A3.

As described above, the inductor L6 is formed by the inductor conductor layers 606, 616, 626, 636, 676, and 686 and the plurality of through holes connected to those conductor layers. In FIG. 14 to FIG. 16, the reference numeral A6 denotes an axis that passes through the opening L60 of the inductor L6 and extends in a direction parallel to the stacking direction T. The conductor layers 606, 616, 626, 636, 676, and 686 as a whole are wound about the axis A6. Particularly in the example embodiment, each of the conductor layers 606, 616, 626, 636, 676, and 686 is wound about the axis A6.

The inductor L3 and the inductor L6 are arranged so that an opening L30 of the inductor L3 and the opening L60 of the inductor L6 do not face each other. Particularly in the example embodiment, the inductor L3 and the inductor L6 are arranged to be arrayed in the X direction in such a posture that the openings L30 and L60 face the first surface 50A of the multilayer stack 50.

Here, a third region R3 and a fourth region R4 that are defined by the inductors L3 and L6 are described. As illustrated in FIG. 14 and FIG. 15, the third region R3 is a planar region, and is an imaginary rectangular region including four sides R3a, R3b, R3c, and R3d. When seen in the stacking direction T, each of the four sides R3a, R3b, R3c, and R3d overlaps with the outer edge of the conductor layer forming one of the inductor L3 and the inductor L6, and does not overlap with a portion except for the outer edge of the conductor forming the other of the inductor L3 and the inductor L6.

The first side R3a is located at the end of the third region R3 in the −X direction, and extends in a direction parallel to the Y direction. The first side R3a overlaps with the outer edge of each of the conductor layers 673 and 683 when seen in the stacking direction T.

The second side R3b is located at the end of the third region R3 in the X direction, and extends in a direction parallel to the Y direction. The second side R3b overlaps with the outer edge of each of the conductor layers 626, 636, 676, and 686 when seen in the stacking direction T.

The third side R3c is located at the end of the third region R3 in the −Y direction, and extends in a direction parallel to the X direction. The third side R3c overlaps with the outer edge of each of the conductor layers 623, 626, 633, 636, 673, 676, 683, and 686 when seen in the stacking direction T.

The fourth side R3d is located at the end of the third region R3 in the Y direction, and extends in a direction parallel to the X direction. The fourth side R3d overlaps with the outer edges of the conductor layers 606 and 616 when seen in the stacking direction T.

As illustrated in FIG. 16, the fourth region R4 is a planar region, and is an imaginary rectangular region including four sides R4a, R4b, R4c, and R4d. As viewed in the −Y direction being a direction orthogonal to the stacking direction T, each of the four sides R4a, R4b, R4c, and R4d overlaps with the outer edge or the surface of the conductor layer forming one of the inductor L3 and the inductor L6, and does not overlap with a portion except for the outer edge or the surface of the conductor layer forming the other of the inductor L3 and the inductor L6.

The first side R4a is located at the end of the fourth region R4 in the −X direction, and extends in a direction parallel to the Z direction. The first side R4a overlaps with the outer edge of each of the conductor layers 673 and 683 when seen in the −Y direction.

The second side R4b is located at the end of the fourth region R4 in the X direction, and extends in a direction parallel to the Z direction. The second side R4b overlaps with the outer edge of each of the conductor layers 626, 636, 676, and 686 when seen in the −Y direction.

The third side R4c is located at the end of the fourth region R4 in the −Z direction, and extends in a direction parallel to the X direction. The third side R4c overlaps with the surface of the conductor layer 606 when seen in the −Y direction. Note that, in FIG. 16, for the sake of convenience, the third side R4c is illustrated away from the conductor layer 606.

The fourth side R4d is located at the end of the fourth region R4 in the Z direction, and extends in a direction parallel to the X direction. The fourth side R4d overlaps with the surface of each of the conductor layers 683 and 686 when seen in the −Y direction. Note that, in FIG. 16, for the sake of convenience, the fourth side R4d is illustrated away from the conductor layers 683 and 686.

Next, with reference to FIG. 14 to FIG. 16, a relationship between the capacitor C9 and the third and fourth regions R3 and R4 is described. As described above, the capacitor C9 is formed by the conductor layers 636 and 647 and the dielectric layer 63 between those conductor layers. As viewed in the stacking direction T, the conductor layers 636 and 647 are present within the third region R3. In particular, when seen in the stacking direction T, the conductor layer 647 is at a position away from the four sides R3a, R3b, R3c, and R3d of the third region R3. When seen in the −Y direction, the conductor layers 636 and 647 are present within the fourth region R4. In particular, when seen in the −Y direction, the conductor layer 647 is at a position away from the four sides R4a, R4b, R4c, and R4d of the fourth region R4.

Here, it is assumed that a three-dimensional space inside the multilayer stack 50 has a planar shape viewed in the stacking direction T which is the same as that of the third region R3 and a planar shape viewed in the −Y direction which is the same as that of the fourth region R4. The three-dimensional space is also a three-dimensional space defined by the inductors L3 and L6. The conductor layers 636 and 647 forming the capacitor C9 are present in the three-dimensional space. In particular, in the stacking direction T, the conductor layer 647 is located between the conductor layer 606 that is located at the end of the three-dimensional space in the −Z direction and the conductor layers 683 and 686 that are located at the end of the three-dimensional space in the Z direction. Further, the conductor layer 647 is located between the conductor layer 623 and the conductor layer 686 in the stacking direction T.

Next, with reference to FIG. 14 and FIG. 15, features of the inductors L3 and L6 and the plurality of conductor layers forming the capacitor C9 are described. The conductor layer 647 forming the capacitor C9 is electrically connected to the conductor layer 673 forming the inductor L3 via the through holes 64T5, 65T5, and 66T5.

As viewed in the stacking direction T, the conductor layer 647 extends from the conductor layers 623, 633, 673, and 683 forming the inductor L3 toward the conductor layers 606, 616, 626, 636, 676, and 686 forming the inductor L6. The conductor layer 647 extends from the outer sides of the conductor layers 606, 616, 626, 636, 676, and 686 toward the opening L60 of the inductor L6.

Particularly in the example embodiment, the conductor layer 647 extends to overlap with the conductor layer 636 when seen in the stacking direction T. The conductor layer 636 is arranged between the conductor layer 606 and the conductor layer 683 in the stacking direction T. The conductor layer 636 and the conductor layer 647 face each other via the dielectric layer 63. The conductor layer 647 includes a first overlapping portion 647B overlapping with the conductor layer 636 when seen in the stacking direction T.

The conductor layer 647 further includes two non-overlapping portions 647A and 647C that do not overlap with the conductor layer 636 when seen in the stacking direction T. The non-overlapping portion 647A is connected to one end portion of the first overlapping portion 647B. In FIG. 14, the boundary between the non-overlapping portion 647A and the first overlapping portion 647B is indicated with a broken line. The non-overlapping portion 647A is arranged on the outer side of the conductor layer 636 when seen in the stacking direction T. The non-overlapping portion 647A is connected to the conductor layer 673 forming the inductor L3 via the through holes 64T5, 65T5, and 66T5.

The non-overlapping portion 647C is connected to the other end portion of the first overlapping portion 647B. In FIG. 14, the boundary between the non-overlapping portion 647C and the first overlapping portion 647B is indicated with a broken line. The non-overlapping portion 647C overlaps with the opening L60 of the inductor L6 when seen in the stacking direction T. An area of the non-overlapping portion 647C is smaller than an area of the first overlapping portion 647B.

As illustrated in FIG. 14, the conductor layer 647 includes a first end edge 647a and a second end edge 647b that are located at both the ends in the longitudinal direction of the conductor layer 647. The first end edge 647a is also an end edge of the non-overlapping portion 647A. In the longitudinal direction of the conductor layer 647, the first end edge 647a is located on a side opposite to the boundary between the non-overlapping portion 647A and the first overlapping portion 647B. The second end edge 647b is also an end edge of the non-overlapping portion 647C. In the longitudinal direction of the conductor layer 647, the second end edge 647b is located on a side opposite to the boundary between the non-overlapping portion 647C and the first overlapping portion 647B.

The conductor layer 636 extends to surround the opening L60 of the inductor L6. Particularly in the example embodiment, the conductor layer 636 includes a plurality of curve portions. The first overlapping portion 647B overlaps with the curve portion when seen in the stacking direction T. The second end edge 647b of the non-overlapping portion 647C has a shape in conformity with a curve shape of the curve portion of the conductor layer 636. The second end edge 647b may be linear or curved.

As illustrated in FIG. 8B, the conductor layer 636 includes an extending portion 636a having a predetermined length and a smooth outer edge. The extending portion 636a may have a substantially constant width in the transverse direction of the conductor layer 636. Note that “the extending portion having a substantially constant width” includes a portion where a width is slightly changed at the curve portion or a portion where a width is changed due to manufacturing variation, but does not include a portion having a step-like shape or the like where a width is intentionally changed. In the example embodiment, the extending portion includes the plurality of curve portions described above. The conductor layer 636 further includes two connection portions 636b and 636c connected to the extending portion 636a at both the ends in the longitudinal direction of the extending portion 636a. The two connection portions 636b and 636c are connected to the through holes, respectively.

The first overlapping portion 647B overlaps with the extending portion 636a of the conductor layer 636 when seen in the stacking direction T. As illustrated in FIG. 15, the extending portion 636a includes a second overlapping portion 636A that overlaps with the first overlapping portion 647B of the conductor layer 647 when seen in the stacking direction T and forms the capacitor C9 together with the first overlapping portion 647B. In FIG. 15, for the sake of better understanding, the second overlapping portion 636A is hatched. Note that the extending portion 636a is a part of the conductor layer 636, and hence it can also be understood that the conductor layer 636 includes the second overlapping portion 636A.

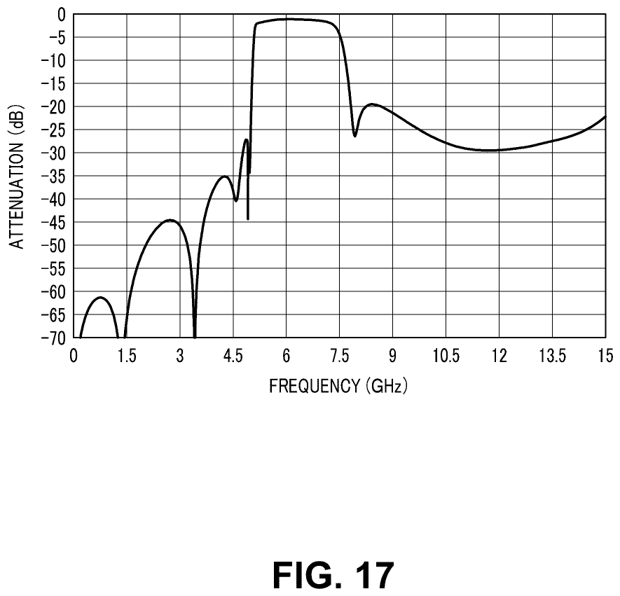

Next, an example of characteristics of the electronic component 1 according to the example embodiment is presented. FIG. 17 is a characteristic chart illustrating an example of pass attenuation characteristics of the electronic component 1. In FIG. 17, the horizontal axis represents frequency, and the vertical axis represents attenuation. It is understood from FIG. 17 that the electronic component 1 has sufficient characteristics for practical use as a band-pass filter.

Next, actions and effects of the multilayer electronic component 5 according to the example embodiment are described. The multilayer electronic component 5 according to the example embodiment includes the inductor L3 and the inductor L6. A plurality of elements are provided between the inductor L3 and the inductor L6 in circuit configuration. In such a configuration, when inductive coupling between the inductor L3 and the inductor L6 is strong, desired characteristics may not be obtained. In contrast, in the example embodiment, the inductor L3 and the inductor L6 are arranged so that the opening L30 of the inductor L3 and the opening L60 of the inductor L6 do not face each other. With this, according to the example embodiment, desired characteristics can be achieved while preventing the function of each of the inductors L3 and L6 from being impaired.

The multilayer electronic component 5 according to the example embodiment includes the capacitor C9 that achieves capacitive cross-coupling between the inductor L3 and the inductor L6. In the example embodiment, even when the plurality of elements are provided between the inductor L3 and the inductor L6, the inductor L3 and the inductor L6 are arranged to be arrayed. With this, according to the example embodiment, the capacitor C9 is provided easily within the multilayer stack 50 of the multilayer electronic component 5.

In the example embodiment, the conductor layer 647 forming the capacitor C9 includes the first overlapping portion 647B overlapping with the inductor conductor layer 636 forming the inductor L6, when seen in the stacking direction T. With this, according to the example embodiment, the capacitor C9 having a predetermined function can be achieved without using a conductor layer other than the conductor layer 636 facing the conductor layer 647. According to the example embodiment, a part of the conductor layer 636 faces the first overlapping portion 647B. With this, the function of the capacitor C9 can be achieved without impairing the function of the inductor L6. According to the example embodiment, the multilayer electronic component 5 can be reduced in size as compared to a case in which the capacitor C9 is configured without using the conductor layer 636.

In the example embodiment, when seen in the stacking direction T, the conductor layer 647 is present within the third region R3 defined by the inductors L3 and L6. With this, according to the example embodiment, the multilayer electronic component 5 can be reduced in size as compared to a case in which the conductor layer 647 is present outside the third region R3. Similarly, when seen in the −Y direction, the conductor layer 647 is present within the fourth region R4 defined by the inductors L3 and L6. With this, according to the example embodiment, the multilayer electronic component 5 can be reduced in size as compared to a case in which the conductor layer 647 is present outside the fourth region R4.

In the example embodiment, the conductor layer 636 overlapping with the first overlapping portion 647B is arranged between the conductor layers 606 and 686 in the stacking direction T, the conductor layers 606 and 686 being other two conductor layers forming the inductor L6. According to the example embodiment, the multilayer electronic component 5 can be reduced in size as compared to a case in which the conductor layer forming the capacitor C9 is arranged at a position closer to the second surface 50B of the multilayer stack 50 with respect to the conductor layer 606 or a case in which the conductor layer forming the capacitor C9 is arranged at a position closer to the first surface 50A of the multilayer stack 50 with respect to the conductor layer 686.

In the example embodiment, the conductor layer 647 includes the non-overlapping portions 647A and 647C in addition to the first overlapping portion 647B. With this, according to the example embodiment, even when each of the conductor layers 636 and 647 is deviated in a direction orthogonal to the stacking direction T due to stacking misalignment during manufacturing, fluctuation of an area of the first overlapping portion 647B can be prevented. As a result, according to the example embodiment, deviation of characteristics of the multilayer electronic component 5 due to stacking misalignment during manufacturing can be prevented.

In the example embodiment, a group of the inductors L2 and L3 and the capacitor C3 has features similar to those of a group of the inductors L3 and L6 and the capacitor C9. In other words, in the example embodiment, the inductor L2 and the inductor L3 are arranged so that the opening of the inductor L2 and the opening L30 of the inductor L3 do not face each other. The conductor layer 642 forming the capacitor C3 includes the overlapping portion that overlaps the inductor conductor layer 633 forming the inductor L3, when seen in the stacking direction T. With this, according to the example embodiment, the multilayer electronic component 5 can be reduced in size while preventing the function of each of the inductors L2 and L3 from being impaired.

Next, other effects of the multilayer electronic component 5 according to the example embodiment are described. In the example embodiment, the opening L30 of the inductor L3 is mostly present in the second region R2, and the opening L60 of the inductor L6 is entirely present in the second region R2. With this, according to the example embodiment, desired characteristics can be achieved while preventing mutual interaction of an electro-magnetic field between each of the inductors L3 and L6 and the mounting member 80.

Similarly, in the example embodiment, the opening of each of the inductors L2 and L7 is entirely present in the second region R2, and the opening of the inductor L5 is mostly present in the second region R2. With this, according to the example embodiment, desired characteristics can be achieved while preventing mutual interaction of an electro-magnetic field between each of the inductors L2, L5, and L7 and the mounting member 80.

Note that the present disclosure is not limited to the example embodiment described above, and various modifications can be made thereto. For example, the electronic component including the multilayer electronic component of the present disclosure is applicable not only to a band-pass filter but also to other filters such as a low-pass filter and a high-pass filter, and is applicable to an electronic component including a plurality of resonators, such as a branching filter that splits a plurality of signals in different frequency bands.

As described above, a multilayer electronic component according to a first aspect of one embodiment of the present disclosure includes a first inductor, a second inductor, a capacitor, and a multilayer stack configured to integrate the first inductor, the second inductor, and the capacitor with each other and including a plurality of dielectric layers stacked together. The first inductor includes at least one first inductor conductor layer wound about a first axis extending in a direction parallel to a stacking direction of the plurality of dielectric layers. The second inductor includes at least one second inductor conductor layer wound about a second axis extending in a direction parallel to the stacking direction. The first inductor and the second inductor are arranged so that a first opening surrounded by the at least one first inductor conductor layer and a second opening surrounded by the at least one second inductor conductor layer do not overlap with each other when seen in the stacking direction. The capacitor includes a capacitor conductor layer. The capacitor conductor layer includes a first overlapping portion extending from the at least one second inductor conductor layer toward the at least one first inductor conductor layer when seen in the stacking direction and overlapping with the at least one first inductor conductor layer when seen in the stacking direction.

Note that, in the multilayer electronic component according to the first aspect of one embodiment of the present disclosure, the at least one first inductor conductor layer may be a single first inductor conductor layer or may include a plurality of first inductor layers. As long as the requirement that the plurality of first inductor conductor layers as a whole are wound about the first axis is satisfied, each of the plurality of first inductor conductor layers may have a shape, such as a linear shape, that is not wound about the first axis. Similarly, the at least one second inductor conductor layer may be a single second inductor conductor layer or may include a plurality of second inductor conductor layers. As long as the requirement that the plurality of second inductor conductor layers as a whole are wound about the second axis is satisfied, each of the plurality of second inductor conductor layers may have a shape, such as a linear shape, that is not wound about the second axis.

In the multilayer electronic component according to the first aspect of one embodiment of the present disclosure, the capacitor conductor layer may be electrically connected to the at least one second inductor layer.

In the multilayer electronic component according to the first aspect of one embodiment of the present disclosure, the at least one first inductor conductor layer may include a second overlapping portion overlapping with the first overlapping portion when seen in the stacking direction and forming the capacitor together with the first overlapping portion. The at least one first inductor conductor layer may include an extending portion having a predetermined length and a smooth outer edge. The second overlapping portion may be a part of the extending portion.

In the multilayer electronic component according to the first aspect of one embodiment of the present disclosure, the capacitor conductor layer may be present within an imaginary rectangular region including four sides when seen in the stacking direction. As viewed in the stacking direction, each of the four sides may overlap with an outer edge of one of the at least one first inductor conductor layer and the at least one second inductor conductor layer, and may not overlap with a portion except for an outer edge of the other of the at least one first inductor conductor layer and the at least one second inductor conductor layer.

In the multilayer electronic component according to the first aspect of one embodiment of the present disclosure, the at least one first inductor conductor layer may include a plurality of first inductor conductor layers. The plurality of first inductor conductor layers may include a first specific inductor conductor layer and a second specific inductor conductor layer that are arranged at a predetermined interval in the stacking direction. The capacitor conductor layer may be arranged between the first specific inductor conductor layer and the second specific inductor conductor layer in the stacking direction. The plurality of first inductor conductor layers may further include a third specific inductor conductor layer arranged between the first specific inductor conductor layer and the second specific inductor conductor layer in the stacking direction. The first overlapping portion may overlap with the third specific inductor conductor layer when seen in the stacking direction. The at least one second inductor conductor layer may include a plurality of second inductor conductor layers. The plurality of second inductor conductor layers may include a third specific inductor conductor layer located at a distal end of one direction parallel to the stacking direction and a fourth specific inductor conductor layer located at a distal end of a direction opposite to the one direction. The capacitor conductor layer may be arranged between the third specific inductor conductor layer and the fourth specific inductor conductor layer in the stacking direction.

In the multilayer electronic component according to the first aspect of one embodiment of the present disclosure, the capacitor conductor layer may further include a non-overlapping portion being connected to the first overlapping portion and overlapping with the first opening when seen in the stacking direction. An area of the non-overlapping portion may be smaller than an area of the first overlapping portion. The non-overlapping portion may include an end edge having a shape in conformity with a curve shape of the at least one first inductor conductor layer.

In the multilayer electronic component according to the first aspect of one embodiment of the present disclosure, the first inductor may include a first end and a second end. The capacitor may be connected between the first end and the second end of the first inductor in circuit configuration.

A multilayer electronic component according to a second aspect of one embodiment of the present disclosure includes an inductor, a capacitor, and a multilayer stack configured to integrate the inductor and the capacitor with each other and including a plurality of dielectric layers stacked together. The inductor includes at least one inductor conductor layer wound about an axis extending in a direction parallel to a stacking direction of the plurality of dielectric layers. The at least one inductor conductor layer includes an extending portion having a predetermined length and a smooth outer edge. The capacitor includes a capacitor conductor layer. The capacitor conductor layer includes a first overlapping portion extending from an outer side of the at least one inductor conductor layer toward an opening surrounded by the at least one inductor conductor layer when seen in the stacking direction and overlapping with the extending portion when seen in the stacking direction.

Note that, in the multilayer electronic component according to the second aspect of one embodiment of the present disclosure, the at least one inductor conductor layer may be a single inductor conductor layer or may include a plurality of inductor conductor layers. As long as the requirement that the plurality of inductor conductor layers as a whole are wound about the above-mentioned axis is satisfied, each of the plurality of inductor conductor layers may have a shape, such as a linear shape, that is not wound about the above-mentioned axis.

In the multilayer electronic component according to the second aspect of one embodiment of the present disclosure, the extending portion may include a second overlapping portion overlapping with the first overlapping portion when seen in the stacking direction and forming the capacitor together with the first overlapping portion.

In the multilayer electronic component according to the second aspect of one embodiment of the present disclosure, the at least one inductor conductor layer may include a plurality of inductor conductor layers. The plurality of inductor conductor layers may include a first specific inductor conductor layer and a second specific inductor conductor layer that are arranged at a predetermined interval in the stacking direction. The capacitor conductor layer may be arranged between the first specific inductor conductor layer and the second specific inductor conductor layer in the stacking direction. The plurality of inductor conductor layers may further include a third specific inductor conductor layer arranged between the first specific inductor conductor layer and the second specific inductor conductor layer in the stacking direction. The first overlapping portion may overlap with the third specific inductor conductor layer when seen in the stacking direction.

In the multilayer electronic component according to the second aspect of one embodiment of the present disclosure, the capacitor conductor layer may further include a non-overlapping portion being connected to the first overlapping portion and overlapping with the opening when seen in the stacking direction. An area of the non-overlapping portion may be smaller than an area of the first overlapping portion. The non-overlapping portion may include an end edge having a shape in conformity with a curve shape of the at least one inductor conductor layer.

In the multilayer electronic component according to the second aspect of one embodiment of the present disclosure, the inductor may include a first end and a second end. The capacitor may be connected between the first end and the second end of the inductor in circuit configuration.

In the multilayer electronic component according to the first aspect of the present disclosure, the capacitor conductor layer includes a first overlapping portion overlapping with the at least one first inductor conductor layer when seen in the stacking direction. With this, the multilayer electronic component according to the first aspect of the present disclosure can be reduced in size without impairing a function of each of an inductor and a capacitor.

In the multilayer electronic component according to the second aspect of the present disclosure, the capacitor conductor layer includes a first overlapping portion overlapping with the at least one inductor conductor layer when seen in the stacking direction. With this, the multilayer electronic component according to the second aspect of the present disclosure can be reduced in size without impairing a function of each of an inductor and a capacitor.

Obviously, many modifications and variations of the present disclosure are possible in the light of the above teachings. Thus, it is to be understood that, within the scope of the appended claims and equivalents thereof, the present disclosure may be practiced in other embodiments than the example embodiment described above.

What is claimed is:

1. A multilayer electronic component comprising:
a first inductor;
a second inductor;
a capacitor; and
a multilayer stack configured to integrate the first inductor, the second inductor, and the capacitor with each other and including a plurality of dielectric layers stacked together, wherein
the first inductor includes at least one first inductor conductor layer wound about a first axis extending in a direction parallel to a stacking direction of the plurality of dielectric layers,
the second inductor includes at least one second inductor conductor layer wound about a second axis extending in a direction parallel to the stacking direction,
the first inductor and the second inductor are arranged so that a first opening surrounded by the at least one first inductor conductor layer and a second opening surrounded by the at least one second inductor conductor layer do not overlap with each other when seen in the stacking direction,
the capacitor includes a capacitor conductor layer, and
the capacitor conductor layer includes a first overlapping portion extending from the at least one second inductor conductor layer toward the at least one first inductor conductor layer when seen in the stacking direction and overlapping with the at least one first inductor conductor layer when seen in the stacking direction.

2. The multilayer electronic component according to claim 1, wherein the capacitor conductor layer is electrically connected to the at least one second inductor conductor layer.

3. The multilayer electronic component according to claim 1, wherein the at least one first inductor conductor layer includes a second overlapping portion overlapping with the first overlapping portion when seen in the stacking direction and forming the capacitor together with the first overlapping portion.

4. The multilayer electronic component according to claim 3, wherein
the at least one first inductor conductor layer includes an extending portion having a predetermined length and a smooth outer edge, and
the second overlapping portion is a part of the extending portion.

5. The multilayer electronic component according to claim 1, wherein
the capacitor conductor layer is present within an imaginary rectangular region including four sides when seen in the stacking direction, and
when seen in the stacking direction, each of the four sides overlaps with an outer edge of one of the at least one first inductor conductor layer and the at least one second inductor conductor layer, and does not overlap with a portion except for an outer edge of the other of the at least one first inductor conductor layer and the at least one second inductor conductor layer.

6. The multilayer electronic component according to claim 1, wherein
the at least one first inductor conductor layer includes a plurality of first inductor conductor layers,
the plurality of first inductor conductor layers includes a first specific inductor conductor layer and a second specific inductor conductor layer that are arranged at a predetermined interval in the stacking direction, and
the capacitor conductor layer are arranged between the first specific inductor conductor layer and the second specific inductor conductor layer in the stacking direction.

7. The multilayer electronic component according to claim 6, wherein
the plurality of first inductor conductor layers further include a third specific inductor conductor layer arranged between the first specific inductor conductor layer and the second specific inductor conductor layer in the stacking direction, and
the first overlapping portion overlaps with the third specific inductor conductor layer when seen in the stacking direction.

8. The multilayer electronic component according to claim 6, wherein
the at least one second inductor conductor layer includes a plurality of second inductor conductor layers,
the plurality of second inductor conductor layers includes a third specific inductor conductor layer located at a distal end of one direction parallel to the stacking direction and a fourth specific inductor conductor layer located at a distal end of a direction opposite to the one direction, and
the capacitor conductor layer is arranged between the third specific inductor conductor layer and the fourth specific inductor conductor layer in the stacking direction.

9. The multilayer electronic component according to claim 1, wherein the capacitor conductor layer further includes a non-overlapping portion being connected to the first overlapping portion and overlapping with the first opening when seen in the stacking direction.

10. The multilayer electronic component according to claim 9, wherein an area of the non-overlapping portion is smaller than an area of the first overlapping portion.

11. The multilayer electronic component according to claim 9, wherein the non-overlapping portion includes an end edge having a shape in conformity with a curve shape of the at least one first inductor conductor layer.

12. The multilayer electronic component according to claim 1, wherein
the first inductor includes a first end and a second end, and
the capacitor is connected between the first end and the second end of the first inductor in circuit configuration.

13. A multilayer electronic component comprising:
an inductor;
a capacitor;
a multilayer stack configured to integrate the inductor and the capacitor with each other and including a plurality of dielectric layers stacked together, wherein
the inductor includes at least one inductor conductor layer wound about an axis extending in a direction parallel to a stacking direction of the plurality of dielectric layers,
the at least one inductor conductor layer includes an extending portion having a predetermined length and a smooth outer edge,
the capacitor includes a capacitor conductor layer, and
the capacitor conductor layer includes a first overlapping portion extending from an outer side of the at least one inductor conductor layer toward an opening surrounded by the at least one inductor conductor layer when seen in the stacking direction and overlapping with the extending portion when seen in the stacking direction.

14. The multilayer electronic component according to claim 13, wherein the extending portion includes a second overlapping portion overlapping with the first overlapping portion when seen in the stacking direction and forming the capacitor together with the first overlapping portion.

15. The multilayer electronic component according to claim 13, wherein
the at least one inductor conductor layer includes a plurality of inductor conductor layers,
the plurality of inductor conductor layers include a first specific inductor conductor layer and a second specific inductor conductor layer that are arranged at a predetermined interval in the stacking direction, and
the capacitor conductor layer is arranged between the first specific inductor conductor layer and the second specific inductor conductor layer in the stacking direction.

16. The multilayer electronic component according to claim 15, wherein
the plurality of inductor conductor layers further include a third specific inductor conductor layer arranged between the first specific inductor conductor layer and the second specific inductor conductor layer in the stacking direction, and
the first overlapping portion overlaps with the third specific inductor conductor layer when seen in the stacking direction.

17. The multilayer electronic component according to claim 13, wherein the capacitor conductor layer further includes a non-overlapping portion being connected to the first overlapping portion and overlapping with the opening when seen in the stacking direction.

18. The multilayer electronic component according to claim 17, wherein an area of the non-overlapping portion is smaller than an area of the first overlapping portion.

19. The multilayer electronic component according to claim 17, wherein the non-overlapping portion includes an end edge having a shape in conformity with a curve shape of the at least one inductor conductor layer.

20. The multilayer electronic component according to claim 13, wherein
the inductor includes a first end and a second end, and
the capacitor is connected between the first end and the second end of the inductor in circuit configuration.
